(19) United States
(12) Patent Application Publication
(10) Pub. No.: US 2023/0262902 A1
(43) Pub. Date: Aug. 17, 2023

(54) SYSTEM WITH ELECTRONIC FUNCTIONALITY IN A FLEXIBLE MEDIUM AND METHODS OF MANUFACTURING THE SAME

(71) Applicant: Advanced Functional Fabrics of America, Inc., Cambridge, MA (US)

(72) Inventors: Jason Cox, Ashland, MA (US); Tairan Wang, Chelmsford, MA (US); Tsachi Avrahami, Arlington, MA (US); Charlotte Fairless, Watertown, MA (US); Jennifer Thornton, Cambridge, MA (US); Mary Jane Schmuhl, Cambridge, MA (US); Henry Cheung, Cambridge, MA (US); Bruce Thompson, Boston, MA (US); Emily Robertson, Somerville, MA (US)

(21) Appl. No.: 18/192,385

(22) Filed: Mar. 29, 2023

Related U.S. Application Data
(63) Continuation of application No. PCT/US2021/052849, filed on Sep. 30, 2021.
(60) Provisional application No. 63/086,632, filed on Oct. 2, 2020.

(51) Int. Cl. H05K 1/18; H05K 1/11; H05K 1/03; H05K 3/36

(52) U.S. Cl. CPC H05K 1/189; H05K 1/038; H05K 1/111; H05K 3/36; H05K 2201/052; H05K 2201/09972; H05K 2201/10098

(57) ABSTRACT

A system for incorporating electronic functionality into a flexible layer includes a flexible printed circuit board having a spine portion and one or more legs in electronic communication with the spine portion. Multiple pads may be disposed on the flexible printed circuit board. The spine portion and the one or more legs may be structured and arranged to be disposed within one or more pockets of the flexible layer. The system may further include electronic devices, each one of which may be in electronic communication with at least one of the pads. In addition, the system may include a controller in electronic communication with at least one of the pads. The system may be characterized by an absence of any external hard-wire interfaces for communication external to the system.

### CROSS-REFERENCE TO RELATED APPLICATIONS

This application is a continuation of, claims priority to and the benefit of, and incorporates by reference herein in its entirety International Patent Application No. PCT/US2021/052849, which was filed on Sep. 30, 2021 and which claims priority to and the benefit of U.S. Provisional Pat. Application No. 63/086,632, which was filed on Oct. 2, 2020, the content of which is also incorporated by reference herein in its entirety.

### STATEMENT REGARDING FEDERALLY SPONSORED RESEARCH OR DEVELOPMENT

This invention was made with U.S. Government support under Agreement Number W15QKN-16-3-0001 awarded by the Army Contracting Command - New Jersey (ACC-NJ). The Government has certain rights in the invention.

### FIELD OF THE INVENTION

Embodiments of the present invention relate generally to manufacturing and incorporating systems having electronic functionality into flexible mediums and, more specifically, to methods of incorporating a flexible, multi-material printed circuit board and system architecture into a fabric or other soft material, such that the system does not feature any external hard-wire interfaces for communication with devices external to the system.

### BACKGROUND OF THE INVENTION

The incorporation of semiconductor technology within fibers converts traditional fibers, filaments, yarns, and the like into sophisticated devices. These multi-material fibers can endow the textiles into which they are intertwined with functions that may yield services to the end-user.

Over their usable life, all textiles, including those that contain multi-material fibers, should be capable of undergoing significant mechanical and environmental abuse (e.g., bending, stretching, twisting, machine washing, exposure to sunlight, exposure to temperature changes, and so forth) that exposes the textile to a myriad of force types (e.g., tension, compression, torsion, and so forth). Conventional multi-material fibers are limited in their abilities to withstand these stimuli.

Accordingly, a need exists for improved methods of incorporating electronic functionality into textiles and other flexible mediums.

### SUMMARY OF THE INVENTION

In a first aspect, embodiments of the present invention relate to a system for incorporating electronic functionality into a flexible layer (e.g., a fabric). In some embodiments, the system includes a flexible printed circuit board having a spine portion and at least one leg in electronic communication with the spine portion. A plurality of pads may be disposed on the flexible printed circuit board. The spine portion and the at least one leg may be structured and arranged to be disposed within at least one pocket of the flexible layer. The system may further include electronic devices (e.g., temperature sensors, motion sensors, positional sensors, audio sensors, light-emitting devices, audio-emitting devices, heating devices, cooling devices, biosensors, and environmental sensors), each one of which may be in electronic communication with at least one of the pads. In addition, the system may include a controller in electronic communication with at least one of the pads. In some embodiments, the system is characterized by an absence of any external hard-wire interfaces for communication external to the system.

In some implementations, the system may include one or more of: a wirelessly-chargeable power source for providing power to the electronic devices and the controller, a transceiver (e.g., an antenna) for providing wireless communication with a device external to the system (e.g., a wireless satellite device), and a communication bus for providing communications between the electronic devices and the controller (e.g., using the I2C communication protocol). In some variations, the communication bus may be one or more of a 1-Wire bus, a controller area network (CAN) bus, or a Power over Communications (PoC) bus. Alternatively, the controller may be adapted to be in wireless communication with the electronic devices. Advantageously, the system may be dust and/or moisture resistant.

In some variations, one or more of the legs is/are selectively removable from the spine portion and re-attachable to the spine portion. Advantageously, the flexible printed circuit board may be drapeable along multiple axes. More specifically, the system may be structured and arranged to have one or more of: a bending length of between about 1.6 cm and about 2.0 cm, a flexural rigidity of less than about 44 µjoule/m, a minimum bend radius of between about 1 mm and about 6 mm, and/or a thickness of between about 0.05 mm and about 10 mm.

In a second aspect, embodiments of the present invention relate to a textile that includes a fabric defining one or more pockets in which the system may be housed. In some implementations, the fabric includes a planar surface and the system lies within the planar surface and has a thickness of between about 0.05 mm and about 10 mm.

In a third aspect, embodiments of the present invention relate a method of manufacturing a textile that includes the steps of providing a fabric defining one or more pockets and disposing the system within the one of more pockets. In some variations, the method may include selectively removing one of the legs from the spine portion prior to disposing the system within the pocket(s) and/or re-attaching the removed leg to the spine portion prior to disposing the system within the pocket(s).

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 shows a block diagram of a system, in accordance with some embodiments of the present invention;

FIG. 2A shows a block diagram of system architecture, in accordance with some embodiments of the present invention;

FIG. 2B shows an E-shaped base portion of an illustrative system, in accordance with some embodiments of the present invention;

FIG. 2C shows a power supply for an E-shaped base portion of an illustrative system, in accordance with some embodiments of the present invention;

FIG. 3 provides a table of illustrative properties of the system, in accordance with some embodiments of the present invention;

FIG. 4 shows a spine portion having a plurality of open pads for re-attaching legs to the spine portion, in accordance with some embodiments of the present invention;

FIG. 5 shows a plurality of pads disposed on a leg of the E-shaped system shown in FIG. 2A, in accordance with some embodiments of the present invention;

FIG. 6 shows a programming target (FPC stub) disposed on a leg of the E-shaped system shown in FIG. 2A, in accordance with some embodiments of the present invention;

FIGS. 7A and 7B show an illustrative jig having two posts for aligning pins on an electronic device with respective pins on a pad, in accordance with some embodiments of the present invention; and

FIG. 8 shows a textile having a fully-integrated system with a flexible medium having a plurality of pockets, in accordance with some embodiments of the present invention.

### DETAILED DESCRIPTION

### System Architecture

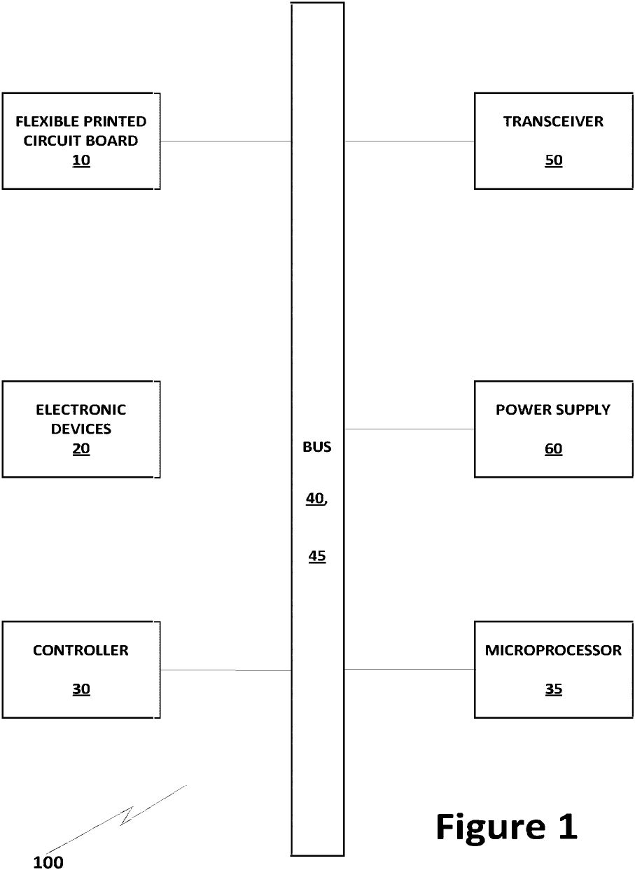

Referring to FIG. 1, a block diagram of an illustrative embodiment of a scalable, rapid-prototyping architecture for a system 100 structured and arranged to be incorporated into a flexible medium (e.g., a fabric, a soft good, and so forth) is shown. The system 100 integrates technical (e.g., semiconductor and integrated circuit) components into the soft, flexible medium as seamlessly as possible. Advantageously, incorporation of the system architecture in the flexible medium does not affect or minimally affects the drapability and/or the mechanical similarity of the flexible medium without the system architecture incorporated therein.

The system 100 is a closed system in which the workings and components of the system 100 are almost imperceptible when disposed in and/or incorporated into the flexible medium and, moreover, the system 100 does not feature any external hard-wire interfaces (referred to herein as “pucks”) for communication with devices external to the system 100. The fully-closed nature of the system 100 when incorporated into a flexible medium facilitates protecting the whole from the external environment.

For example, the system 100, when incorporated into a flexible medium, may be more easily waterproofed (e.g., using Novec™ 2708 electronic grade coating manufactured by 3M™ Corporation of Minneapolis, Minnesota) and/or made moisture- and/or dust-resistant up to comparable IP44 standards. Indeed, because the system 100 is fully-enclosed and includes wireless battery charging, the entire system 100 may be processed (e.g., using vapor deposition, immersion coating, and the like) at the same time. Such waterproofing and/or processing essentially seal the system 100, enabling users to wash (e.g., in a washing machine) the flexible fabric.

In some implementations, the system 100 may include a flexible printed circuit board (FPC) 10 to which a plurality of electronic devices 20 (e.g., integrated circuits, semiconductors, temperature sensors, pressure sensors, strain sensors, motion sensors, positional sensors, inertial measurement units (IMUs), audio sensors, microphones, light-emitting devices, audio-emitting devices, heating devices, cooling devices, biosensors (e.g., for taking bioimpedance measurements and the like), heart rate monitors, respiration monitors, environmental sensors (e.g., for measuring or sensing humidity, VOC, CO, CO₂, O₂, and the like), and so forth) and a processing device(s) (e.g., a controller 30 and a microprocessor(s) 35) may be selectively attached at desired locations (referred to herein as pads 15) on the spine portion 12 and the legs 14. Advantageously, electronic devices 20 incorporated into the flexible medium may be configured and/or adapted to sense, for the purpose of illustration rather than limitation, one or more of: light (e.g., visible, IR, and so forth), temperature, movement/location (e.g., change in location, compression, expansion, proximity to a designated point, and so forth), moisture, pressure (e.g., air pressure, water pressure, applied human pressure, and so forth), change in capacitance, electromagnetic changes, resistive (e.g., potentiometric) changes, (e.g., piezoresistive or piezoelectric) strain, electrical signals, chemicals, radio wavelengths, sound, environmental indicia (e.g., humidity, VOC, CO, CO₂, O₂, and the like) and biometrics (e.g., heart rate, blood pressure, EEG, blood oxygenation, rate of respiration, muscle activity, bioimpedance, and so forth).

In some applications of the invention, a transceiver 50 (e.g., an antenna) may be incorporated into the system 100 for the purpose of providing (e.g., wireless and/or wired) communication to and from the master controller 30. Communication enables users, for example, to control the electronic devices 20, as well as to receive and process data (e.g., data telemetry) therefrom, and, moreover, enables users to interface with external devices (e.g., a remote processing device, a wireless satellite, and the like) in real time. In some variations, wireless communication may be used between the master controller 30 and the electronic devices 20. Alternatively, a master communication bus 40a (e.g., a 1-Wire bus, a controller area network (CAN) bus, a Power over Communications (PoC) bus, or the like) may be used to provide communication (e.g., using an I2C communication protocol or the like) between the master controller 30 and the local microprocessors 35, while a local communication bus 40b may be used on each leg 14a, 14b, ... 14n to provide communication (e.g., using an I2C communication protocol or the like) between the local microprocessors 35 and the electronic devices 20.

A power supply (e.g., a wirelessly-chargeable power supply 60) may be included in the system 100 to provide power to the electronic devices 20, the master controller 30, and transceiver 50. Advantageously, a power bus 45 may be provided for distributing power to the carious components of the system 100.

### Flexible Printed Circuit Board (FPC)

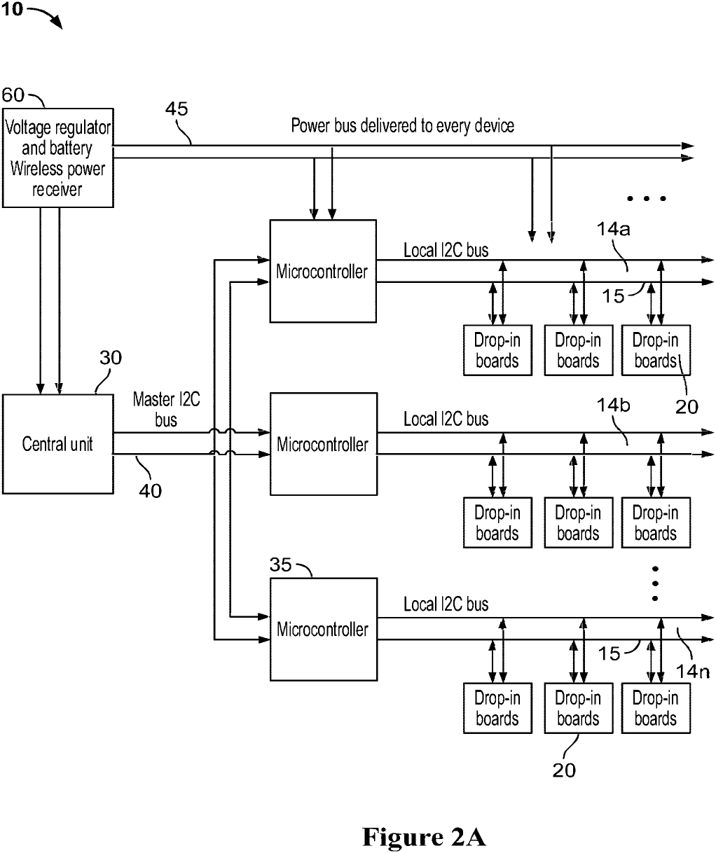

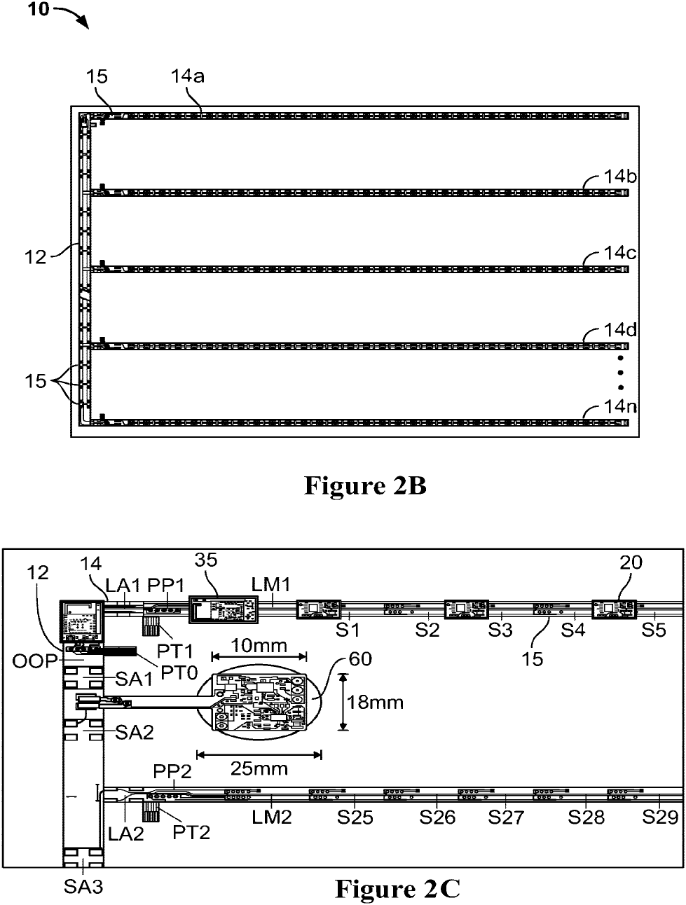

An illustrative embodiment of a FPC 10 for the system 100 is shown in FIGS. 2A and 2B. As previously mentioned, preferably, the incorporation of the FPC 10, including the other components of the system 100, are structured and arranged such that the flexible medium into which the system 100 is incorporated remains, essentially, as drapeable and mechanically similar as the flexible medium without the system 100 added.

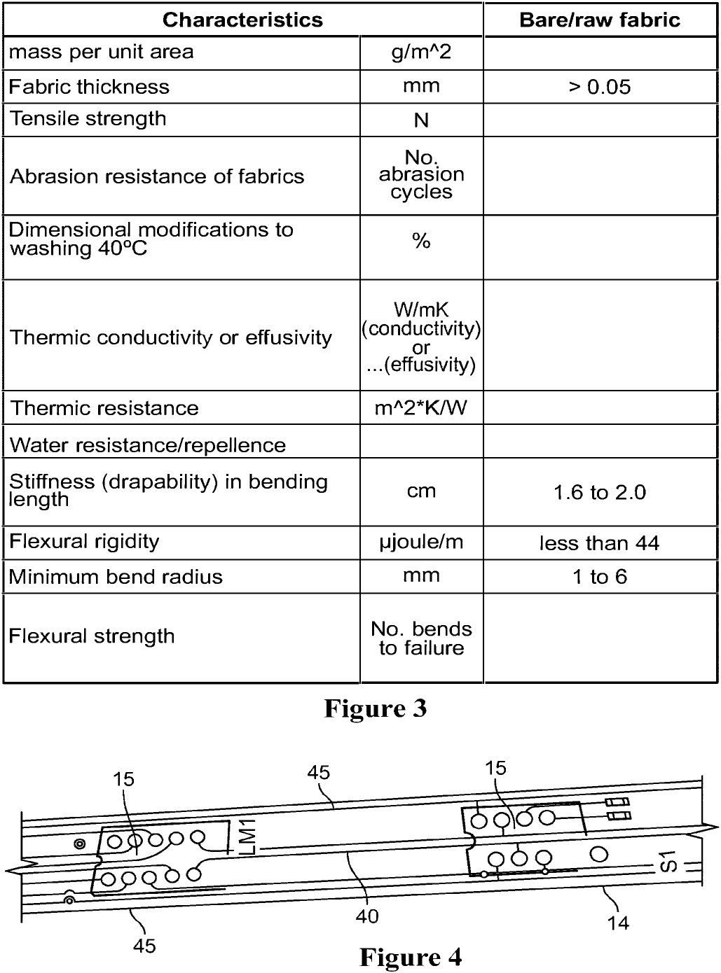

In some implementations, the FPC 10 includes a spine portion 12 to which one or more legs 14a, 14b, ... 14n may be attached. In some implementations, the FPC 10 may be manufactured of a plastic (e.g., a polyamide) having a thickness of about 0.3 mm, a minimum static bending radius of about 3 mm, and a minimum dynamic bending radius of about 6 mm. The range of operating temperatures for the FPC 10 may vary between about -50° C. and about 150° C. Desirable properties of the FPC 10 are summarized in the table in FIG. 3.

Based on ASTM D1388 testing, typical flexible media such as fabrics and textiles may have a bending length of about 1.6 cm. Integration of the FPC 10 may increase the bending length of the entire system about 20 percent (e.g., to about 2.0 cm). However, further optimization of the weight and size of the entire system can decrease the bending length by 20 percent. Flexural rigidity of typical fabrics and textiles may be as low as 20 µjoules/m. However, integrating of the system 100 into such flexible media may increase the flexural rigidity by about 27 percent or more. As a result, the entire system can exhibit a flexural rigidity of about 44 µjoules/m or lower, depending on the fabric/textile choice. Incorporation of the system 100 into a flexible medium may also provide a typical (e.g., minimum) bend radius of between about 1 mm and about 6 mm.

Advantageously, flexural strength of the entire structure may be maximized and bending length of the entire structure may be minimized if the specific layout of traces are such that the neutral bending axis of the FPC 10 is concentrated on a single conductive layer. As a result of concentrating the traces at the neutral axis, the entire system may exhibit increase reliability and greater drapeability. Exemplary measures that may be taken in design to increase reliability and greater drapeability may include, for the purpose of illustration and not limitation: absence of solid conductive planes (to maximize flexural strength), minimize the use of conductive vias (to increase reliability), and placing electronic devices 20 at specific intervals and on the same plane (to increase flexibility between the electronic devices 20).

Although FIGS. 2A and 2B show an E-shaped FPC 10 having a plurality of legs 14a, 14b, ... 14n extending essentially normal (i.e., at or about 90 degrees) from a single side of the spine portion 12, that is done for illustrative purposes only. Those of ordinary skill in the art can appreciate that legs 14a, 14b, ... 14n may be disposed on either side or both sides of the spine portion 12 and, in additional, may stem from the spine portion 12 at any desired angle. For illustrative purposes only, the legs 14a, 14b, ... 14n are depicted as being linear. In some variations, the legs 14a, 14b, ... 14n may be curved, fish-hooked, and/or follow a serpentine pattern.

Advantageously, legs 14a, 14b, ... 14n are structured and arranged to be selectively removable and re-attachable to the spine portion 12. For example, referring to FIG. 4, an embodiment of a spine portion 12 is shown having a plurality of (e.g., two) open pads 16 and a single leg 14. The leg 14 may be torn, cut, or otherwise removed from the spine portion 12 and relocated and re-attached at any of the open pads 16 disposed on the spine portion 12. In some variations, each open pad 16 includes connections (e.g., pins) for the master communication bus 40a and for the power bus 45, which are available for connecting to the local communication bus 40b and the power bus 45 disposed on the re-attached leg 14.

Each of the spine portion 12 and the one or more legs 14a, 14b, ... 14n is structured and arranged to provide a low profile (e.g., to remain essentially in the plane (e.g., within a few millimeters) of the flexible medium) and, moreover, to be (e.g., slidingly) inserted into corresponding pockets formed in the flexible medium. Although the term “pockets” is used to describe the channel(s) or housing(s) for the spine portion 12 and the one or more legs 14a, 14b, . .. 14n, the term is meant to be expansive to include any structure that may be provided in the flexible medium, incorporated into the flexible medium, and so forth for the purpose of housing the spine portion 12 and the one or more legs 14a, 14b, ... 14n. Those of ordinary skill in the art can appreciate that a single, large pocket may be formed in the flexible medium to accommodate the spine portion 12 and the one or more legs 14a, 14b, ... 14n altogether, or, in the alternative, multiple pockets may be formed in the flexible medium to accommodate the spine portion 12 and the one or more legs 14a, 14b, ... 14n separately and individually. Alternatively, a few threads or loops that are configured to accommodate the spine portion 12 and/or one or more of the legs 14a, 14b, ... 14n may be formed (e.g., knit, weaved, or the like) in the flexible medium. Threads and loops may be provided to go around the spine portion 12 and/or legs 14 to hold or retain the spine portion 12 and/or legs 14 against the surface of the flexible medium. Exemplary pockets, for the purpose of illustration rather than limitation, may include woven double cloth pockets, a tubular knit fabric with channels, sewn pockets, bonded pockets, and so forth.

In some implementations, the spine portion 12 may be slightly more rigid than the legs 14a, 14b, ... 14n; hence, manufacturers may design the system 100 and the flexible medium so that the spine portion 12 is located in a portion of the flexible medium that may also be less flexible. For example, the spine portion 12 may be structured and arranged to be incorporated into or near a zipper, a pocket, or a seam in a garment. For example, as shown in FIG. 2C, the controller 30 may be incorporated into the spine portion 12. Portions of the communication bus 40 and the power bus 45 may also be formed in the spine portion 12 of the FPC 10. The controller 30 and the wirelessly-chargeable power supply 60 may be more rigid that one or more electronic devices 20 placed on one or more of the legs 14a, 14b, ... 14n.

Design and manufacture the FPC 10 may include a custom flex layout and/or a “drop in” layout. Custom flex layouts include integrated circuits, passive electronic components (e.g., resistors, capacitors, inductors, other semiconductors, and specific mechanical features such as fiducial markers for alignment, and the like) that are manufactured contemporaneously or substantially contemporaneously with the base portion of the FPC 10. In contrast, in some applications, with a “drop in” layout, a plurality of pads 15 may be formed (e.g., incorporated into) in the base portion at the time of manufacture. In some variations, the pads 15 may include a plurality of pins to which a “dropped-in” electronic device 20 may be operatively attached (e.g., adhered, soldered, and so forth). Advantages of a “drop in” layout include: reduced cost, reduced manufacturing time, flexible employment of electronic devices 20, and greater flexibility in introducing additional electronic devices 20. Advantages of a custom flex layout include a reduced size.

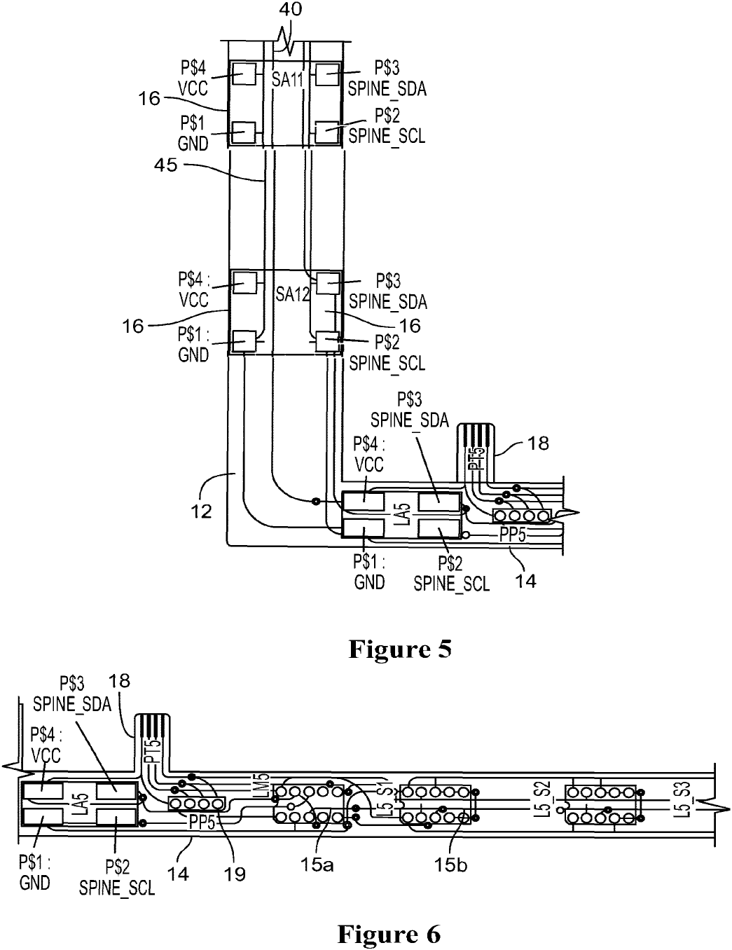

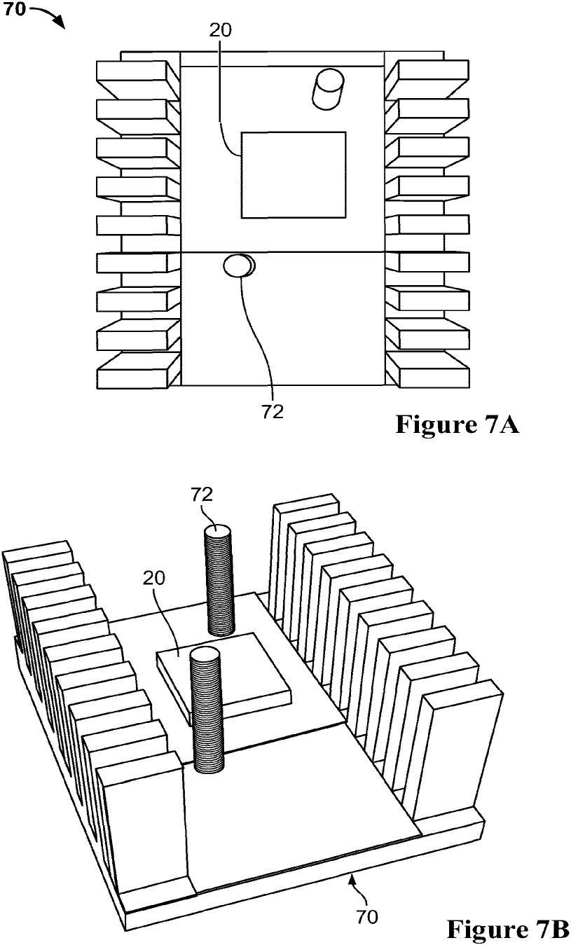

FIG. 5 shows a portion of a leg 14 that includes the flexible base on which may be printed a plurality of pads 15a, 15b that are in electronic communication with the master controller 30 via a communication bus 40a and in electrical communication with the power source 60 via a power bus 45. Spacing between pads 15a, 15b may vary so that rigid components attached to the FPC 10 are spaced far enough apart such that the FPC 10 is still able to bend between the components. As shown in FIG. 6, a local microprocessor 35 (FIG. 1) may be incorporated into the leg 14, such that the local microprocessor 35 is in electrical and electronic communication with a local master pad 15a provided for that purpose on each of the legs 14a, 14b, ... 14n. The electronic devices 20 (FIG. 1) also may be incorporated into any of the drop-in pads 15b disposed on the leg 14, such that the electronic devices 20 are in electrical and electronic communication with the drop-in pad 15b. The local microprocessor 35 may be programmed, inter alia, to communicate with the master controller 30 for the purpose of data telemetry, as well as with the electronic device(s) 20, for the purpose of controlling the electronic device(s) 20 on a respective leg 14a, 14b, ... 14n. Such communication may be wireless or wired (e.g., via the communication bus 40b).

In some applications, as shown in FIG. 6, each leg 14 may also include a programming target (e.g., an FPC stub) 18 that is in electronic communication with the local master pad 15a on any leg 14. Using the FPC stub 18, a processing device (e.g., a breakout board) may be placed in electronic communication with the local microprocessor 35 for the purpose of, for example, (e.g., development) programming the local microprocessor 35. The FPC stub 18 may be removed from the leg 14 once the local microprocessor 35 has been (e.g., development) programmed. In some variations, POGO pins 19 may be provided for future programming requirements.

In one illustrative application, the system 100 and flexible medium may include electronic devices 20 that may be used for temperature sensing for the purpose of providing a multi-point temperature map of an object. In such an application, temperature sensors 20 may be attached to each of the drop-in pads 15b on each of the legs 14a, 14b, ... 14n. Preferably, the temperature sensors 20 are adapted to provide accurate temperature readings within +/- 0.5 degrees Centigrade (°C). In a second application, the system 100 and flexible medium may include electronic devices 20 that may be used for sensing the (e.g., three-dimensional) orientation of the flexible medium for the purpose of providing a mesh map of the flexible medium. In such an application, the positional sensors 20 may be attached to a corresponding drop-in pad 15b on each of the legs 14a, 14b, ... 14n. Preferably, the positional sensors 20 provide x-, y-, and z-coordinates of the orientation of the flexible medium in real-time. In a third application, the system 100 and flexible medium may include electronic devices 20 that may be used for sensing sound from a source for the purpose of detecting directional sound propagation at different locations in the flexible medium. In such an application, the audio sensors 20 (e.g., microphones) may be attached to each of the drop-in pads 15b on each of the legs 14a, 14b, ... 14n for the purpose of detecting directional sound propagation at different locations in the flexible medium.

Those of ordinary skill in the art can appreciate that the electronic devices 20 can include any number of devices. Indeed, in addition to temperature sensors, positional sensors, and audio sensors, the electronic devices 20 may include, for the purpose of illustration rather than limitation: motion sensors, light-emitting devices, audio-emitting devices, heating devices, cooling devices, biosensors, environmental sensors, and so forth. Analog sensors 20, e.g., RTD temperature sensors, may also incorporated into the system 100, for example, using direct analog connections to the microprocessors 35 rather than connecting the sensors 20 directly to the communications bus 40.

### Master Controller and Communication Bus

For data telemetry and other processing functions, a master processing device (e.g., a master controller 30) may be disposed on the spine portion 12 of the FPC 10 in electronic communication with the electronic devices 20 and/or local microprocessors 35 disposed on pads 15 on one or more of the legs 14 extending from the spine portion 12. In some embodiments, communication between the master controller 30, the local microprocessors 35, and the electronic devices 20 may be conducted wirelessly and via wired communication buses 40a, 40b simultaneously. In some variations, a first portion of the communication bus 40a provides communication between the master controller 30 and the local microprocessors 35, while a second portion of the communication bus 40b provides communication between each local microprocessor 35 and the electronic devices 20 disposed on the same leg 14a, 14b, ... 14n as the respective local microprocessor 35.

The master communication bus 40a providing communication between the master controller 30 and the local microprocessors 35 and the local communication bus 40b providing communication between each local microprocessor 35 and the electronic devices 20 enable the system 100 to perform various tasks simultaneously. For example, the master communication bus 40a enables the master controller 30 to talk to and receive aggregated sensor data from each of the local microprocessors 35, while the local communication bus 40b enables local microprocessors 35 to communicate with and aggregate data from the electronic devices 20 on each leg 14a, 14b, ... 14n.

Advantageously, the master controller 30 may be adapted and programmed to aggregate data from the local microprocessors 35 disposed on each of the legs 14a, 14b, ... 14n. Data transmission may be wirelessly, via a wired medium (e.g., using the communication bus 40a), or via a combination of both. A typical (e.g., wired) communication bus 40a, 40b may include a bus suitable for any digital communication system having a plurality of electronic devices 20 with individual addressability. Exemplary communication busses 40a, 40b may include 1-Wire bus, a controller area network (CAN) bus, a Power over Communications (PoC) bus, or the like. Preferably, the communication bus 40a, 40b will provide a minimal number of bus conductors.

### Transceivers

In some implementations, the system 100 may include a plurality of transceivers 50 that are adapted to provide (e.g., wireless) communication from the master controller 30 to one or more of the local microprocessors 35, as well as the communication from the master controller 30 to a remote server and/or processing device (e.g., a wireless satellite and the like).

The external communication network (e.g., between the master controller 30 and remote devices) may include any communication network through which system or network components may exchange data, e.g., the World, Wide Web, the Internet, an intranet, a wide area network (WAN), a local area network (LAN), and so forth. To exchange data via the communication network, the master controller 30 and remote devices may include servers and processing devices that use various methods, protocols, and standards, including, inter alia, Ethernet, TCP/IP, UDP, HTTP, and/or FTP. The remote servers and/or processing devices may include a commercially-available processor such as an Intel Core, Motorola PowerPC, MIPS, UltraSPARC, or Hewlett-Packard PA-RISC processor, but also may be any type of processor or controller as many other processors, microprocessors, and controllers are available. There are many examples of processors currently in use, including network appliances, personal computers, workstations, mainframes, networked clients, servers, media servers, application servers, database servers, and web servers.

The transceivers 50 may be adapted to use I2C communication protocol; however, in other embodiments, the transceiver 50 may use any RF communication protocol available (e.g., Bluetooth, WiFi, Zigbee, Z-Wave, and the like). The use of other RF communication protocols enables the incorporation of any commercial off-the-shelf (COTS) integrated circuit (e.g., as an electronic device 20) into the system 100. Advantageously, I2C communications (via a hardwired communication bus 40) may occur at the same time or at substantially the same time as the wireless communications using the transceivers 50.

Advantageously, because each leg 14a, 14b, ... 14n includes a local microprocessor 35 and a local wireless transceiver 50, these components may act as a redundant channel for transmitting data in the event that the master controller 30 and/or main transceiver 50 fail or are not available. This may occur, for example, if a leg 14a, 14b, ... 14n is removed from the spine portion 12.

Design of a system that does not use pucks contributes to the desirable low-profile system of the present system 100. Hence, low-profile antennas (e.g., copper-wire antennas, textile antennas, and the like) are desirable for the system 100. Exemplary transceivers 50 may include an antenna (e.g., a dipole antenna) incorporated into an intricate embroidery thread such as twisted silver-coated polymer and/or polyamide filaments bundled into strands and/or a plurality of copper wires bundled with polyester and stainless steel to form threads.

### Power Supply

In some embodiments, the power supply 60 may be structured and arranged to provide electrical power (e.g., via the power bus 45) to the master controller 30, the local microprocessors 35, the electronic devices 20, and the transceivers 50. In some applications, the power source 60 may be a single device or, in the alternative, may include distributed power supplies capable of provided power (e.g., about 300-400 mAh) for at least four hours and, more preferably, for between about six and about eight hours. In some variations, a soft, flexible power source having a thickness (or height) of about 2 mm or less may be desirable.

Design of a system that does not use pucks contributes to the desirable low-profile system of the present system 100. Hence, wireless charging (e.g., using Qi wireless power transfer protocols). Typically, Qi charging and battery connections are connected using a relatively high-profile connector. However, lower profile connectors may be achieved by soldering the power supply (e.g., battery) 60 directly to power bus 45. Alternatively, instead of using solder, an adhesive-based connector may be used for the same purpose.

Although the invention is described using a power supply 60 and the Qi wireless power transfer protocol, that is done for illustrative purposes only. Indeed, the system 100 may use other wireless power transfer protocol.

### Method of Manufacturing a Fully-Closed System

In some embodiments, the present invention relates to a textile that includes a flexible medium (e.g., a fabric) that defines one or more pockets and a system that is housed in the pocket(s). Those of ordinary skill in the art can appreciate that a single, large pocket may be formed in the flexible medium to accommodate the spine portion 12 and the one or more legs 14a, 14b, ... 14n altogether, or, in the alternative, multiple pockets may be formed in the flexible medium to accommodate the spine portion 12 and the one or more legs 14a, 14b, ... 14n separately and individually. Alternatively, a few threads and/or loops that are configured to accommodate the spine portion 12 and/or one or more of the legs 14a, 14b, ... 14n may be formed (e.g., knit, weaved, or the like) in the flexible medium. Threads and/or loops may be provided to go around the spine portion 12 and/or legs 14a, 14b, ... 14n to hold or retain the spine portion 12 and/or legs 14a, 14b, ... 14n against the surface of the flexible medium.

Manufacture of such a textile may include providing the flexible medium and disposing all or some portion of the system in the pocket(s). For example, once the spine portion 12 and legs 14a, 14b, ... 14n have been manufactured, one or more electronic devices (i.e., functional drop-in boards) 20 may be attached (e.g., soldered, adhered, and the like) to corresponding pads 15 disposed on the spine portion 12 or legs 14a, 14b, ... 14n. In one application, a solder, adhesive, and the like may be applied to the pins on the pads 15 at the time of manufacture. Subsequently, the pins on the electronic device (i.e., functional drop-in board) 20 may be aligned with and placed against respective pins on the pad 15. Once the pins are properly aligned, the pins on the electronic device (i.e., functional drop-in board) 20 may be adhered to/soldered to respective pins on the pad 15. In some implementations, the solder on the pins of the pads 15 may be heated (e.g., in a solder reflow oven), causing the solder to flow to complete the attachment.

In one implementation, to facilitate properly aligning the pins of the electronic device (i.e., functional drop-in board) 20 with respective pins on the pad 15, small holes may be formed in the spine portion 12 and/or leg(s) 14a, 14b, ... 14n proximate the pads 15. In some variations, small holes may also be formed in the electronic device (i.e., functional drop-in board) 20. Referring to FIGS. 7A and 7B, the electronic device (i.e., functional drop-in board) 20 and in the spine portion 12 and/or leg(s) 14a, 14b, ... 14n may then be aligned using a (e.g., thermally-conductive, aluminum) jig 70 having a plurality of posts 72 that are structured and arranged to facilitate such alignment. For example, the posts 72 may pass through the small holes formed in the spine portion 12 and/or leg(s) 14a, 14b, ... 14n proximate the pads 15, as well as in the electronic device (i.e., functional drop-in board) 20, aligning the pins of the electronic device (i.e., functional drop-in board) 20 with the pins on the pad 15. Once the pins are properly aligned, the underside of the jig 70 may then be heated (e.g., using a solder reflow oven) so that the solder on the pins flows, fixedly attaching the pins of the electronic device (i.e., functional drop-in board) 20 to the pins on the pads 15.

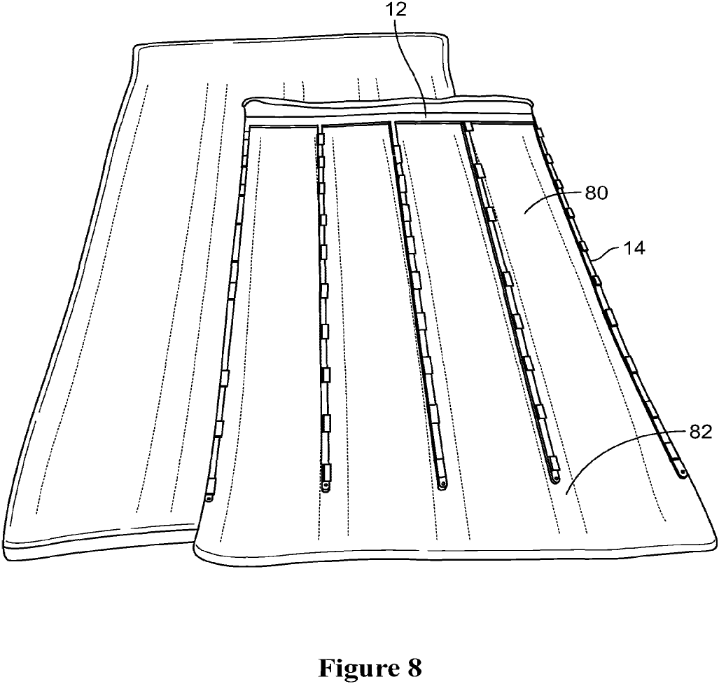

Once the system 100 has been manufactured, the system 100 may be incorporated into a flexible medium (e.g., a knit or woven swatch of material). For example, referring to FIG. 8, an E-shaped system 100 and a flexible medium 80 are shown. The flexible medium 80 includes a plurality of channels, pockets, and the like 82 that have been pre-formed in the flexible medium specifically for the purpose of receiving and retaining the spine portion 12 and/or leg(s) 14a, 14b, ... 14n.

Having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

1. A system for incorporating electronic functionality into a flexible layer, the system comprising:
a flexible printed circuit board comprising a spine portion and at least one leg in electronic communication with the spine portion, wherein a plurality of pads are disposed on the flexible printed circuit board and wherein the spine portion and the at least one leg are structured and arranged to be disposed within at least one pocket of the flexible layer;
a plurality of electronic devices, each electronic device in electronic communication with at least one of the pads; and
a controller in electronic communication with at least one of the pads,
wherein the system is characterized by an absence of any external hard-wire interfaces for communication external to the system.

2. The system of claim 1 further comprising a wirelessly-chargeable power source for providing power to the plurality of electronic devices and the controller.

3. The system of claim 1 further comprising a transceiver for providing wireless communication with a device external to the system.

4. The system of claim 3, wherein the device external to the system is a wireless satellite device.

5. The system of claim 3, wherein the transceiver comprises an antenna.

6. The system of claim 1, wherein the flexible layer comprises a fabric.

7. The system of claim 1, wherein any leg of the at least one leg is selectively removable from the spine portion.

8. The system of claim 7, wherein any removed leg is re-attachable to the spine portion.

9. The system of claim 1, wherein the flexible printed circuit board is drapeable along multiple axes.

10. The system of claim 1, wherein the system is structured and arranged to have a bending length of between about 1.6 cm and about 2.0 cm.

11. The system of claim 1, wherein the system is structured and arranged to have a flexural rigidity of less than about 44µjoule/m.

12. The system of claim 1, wherein the system is structured and arranged to have a minimum bend radius of between about 1 mm and about 6 mm.

13. The system of claim 1, wherein the system is structured and arranged to have a thickness of between about 0.05 mm and about 10 mm.

14. The system of claim 1, wherein the electronic devices are selected from the group consisting of temperature sensors, motion sensors, positional sensors, audio sensors, light-emitting devices, audio-emitting devices, heating devices, cooling devices, biosensors, and environmental sensors.

15. The system of claim 1 further comprising a communication bus for providing communications between the plurality of electronic devices and the controller.

16. The system of claim 15, wherein the communication bus is selected from the group consisting of a 1-Wire bus, a controller area network (CAN) bus, and a Power over Communications (PoC) bus.

17. The system of claim 15, wherein the communications over the communication bus use the I2C communication protocol.

18. The system of claim 1, wherein the controller is adapted to be in wireless communication with the plurality of electronic devices.

19. The system of claim 1, wherein the system is at least one of dust or moisture resistant.

20. A textile, comprising:
a fabric defining at least one pocket; and
the system of claim 1 housed within the at least one pocket.

21. The textile of claim 20, wherein the fabric comprises a planar surface and further wherein the system lies within the planar surface.

22. The textile of claim 21, wherein the system lying within the planar surface has a thickness of between about 0.05 mm and about 10 mm.

23. A method of manufacturing a textile, the method comprising the steps of:
providing a fabric defining at least one pocket; and
disposing the system of claim 1 within the at least one pocket.

24. The method of claim 23 further comprising selectively removing one of the legs from the spine portion prior to disposing the system within the at least one pocket.

25. The method of claim 24 further comprising re-attaching the removed leg to the spine portion prior to disposing the system within the at least one pocket.
